(19) United States
(12) Patent Application Publication
(10) Pub. No.: US 2016/0380145 A1
(43) Pub. Date: Dec. 29, 2016

(54) METHODS OF FORMING HIGH-EFFICIENCY SOLAR CELL STRUCTURES

(71) Applicants: Eugene A. Fitzgerald, Windham, NH (US); Arthur J. Pitera, Brookline, MA (US); Steven A. Ringel, Bexley, OH (US)

(72) Inventors: Eugene A. Fitzgerald, Windham, NH (US); Arthur J. Pitera, Brookline, MA (US); Steven A. Ringel, Bexley, OH (US)

(21) Appl. No.: 14/612,677

(22) Filed: Feb. 3, 2015

Related U.S. Application Data
(63) Continuation of application No. 12/474,877, filed on May 29, 2009, now abandoned.
(60) Provisional application No. 61/059,946, filed on Jun. 9, 2008.

(51) Int. Cl. H01L 31/18; H01L 31/0304; H01L 31/02; H01L 31/0735

(52) U.S. Cl. CPC H01L 31/184; H01L 31/0735; H01L 31/0304; H01L 31/02008

(57) ABSTRACT

Methods for forming solar cells include forming, over a substrate, a first junction comprising at least one III-V material and having a threading dislocation density of less than approximately 10⁷ cm⁻², and forming, over the first junction, a cap layer comprising silicon, wherein the substrate consists essentially of silicon.

### CROSS-REFERENCE TO RELATED APPLICATIONS

This application is a continuation of U.S. patent application Ser. No. 12/474,877, filed on May 29, 2009, which claims priority to and the benefit of U.S. Provisional Patent Application Ser. No. 61/059,946, filed on Jun. 9, 2008. The entire disclosure of each of these applications is incorporated by reference herein.

### GOVERNMENT SUPPORT

This invention was made with United States Government support under Contract No. W31P4Q-08-C-0031 awarded by the Defense Advanced Research Projects Agency. The United States Government has certain rights in the invention.

### TECHNICAL FIELD

The present invention relates, in various embodiments, to the construction and fabrication of high-efficiency solar cells.

### BACKGROUND

III-V multi-junction solar cells have experienced vast improvements in efficiency over decades of technological progress. The efficiency of III-V multi-junction solar cells increased an average of 1% each year over the last 25 years. By comparison, crystalline silicon solar cells have improved in efficiency by approximately 0.3% annually over a similar period. The leading silicon solar cell technology, by volume, today is multicrystalline silicon, which has improved in efficiency by less than 0.2% per year over the last 20 years. Thus, the physics of III-V multi-junction solar cells have the greatest potential for increasing solar cell efficiency based on historical improvement data. In addition, laboratory records approaching 25% appear to be near the limit for crystalline silicon efficiency, and multicrystalline silicon cells have achieved only approximately 20% efficiency in the laboratory; III-V multi-junction solar cells have the potential to exhibit significantly higher efficiencies.

The number of applications for high-efficiency solar technology increases as cost decreases and weight decreases. Currently, silicon cells are very low cost relative to III-V multi-junction cells. Silicon solar and electronics manufacturing is scaled to much larger volumes, making the per-unit cost of a silicon solar cell much less expensive. III-V multi-junction cell components, by contrast, are deposited on Ge substrates and currently manufactured in dedicated, relatively low-volume facilities equipped to handle only 100 mm diameter wafers. The cost for III-V junction solar cells is measured in dollars per square centimeter, whereas silicon technology cost is measured in dollars per square meter. In addition, Ge has approximately twice the density of silicon, and is therefore a much heavier (and for many applications, a less attractive) substrate for multi-junction III-V technology.

Thus, in order to meet the demand for inexpensive, highly efficient solar cell technology, improved structures and methods for fabricating III-V-based solar cells in a silicon-based manufacturing environment are needed. Such structures will reduce both the weight and cost of high-efficiency solar cell technology, producing high-efficiency cells with very high specific power (i.e., the amount of power generated per weight of the structure).

### SUMMARY

The foregoing limitations of conventional solar cell technology and fabrication processes are herein addressed by solar cell devices having III-V-based active junctions “encapsulated” by silicon, i.e., high-efficiency III-V-based solar cells produced on silicon substrates and having silicon-based capping layers. The silicon encapsulation not only enables the fabrication of III-V substrates on larger, lower-density substrates, but also allows the solar cells to be fabricated in silicon-dedicated facilities.

In one aspect, embodiments of the invention feature a solar cell including a substrate comprising or consisting essentially of silicon. A first junction including or consisting essentially of at least one III-V material and having a threading dislocation density of less than approximately 10⁷ cm⁻² is disposed over the substrate. A cap layer including or consisting essentially of silicon is disposed over the first junction. The III-V material may include or consist essentially of at least one of GaAs, InGaP, AlGaP, AlGaAs, GaP, AlGaSb, GaSb, InP, InAs, InSb, InAlGaP, GaAsP, GaSbP, AlAsP, or AlSbP. The cap layer may consist of doped or undoped silicon. The cap layer may include or consist essentially of a first layer including or consisting essentially of silicon and, disposed thereunder, a second layer including or consisting essentially of at least one of GaP or AlP. The first and second layers may be in direct contact.

The solar cell may include a recess in a surface of the substrate opposed to the first junction. The recess may be substantially filled with at least one non-silicon material, which may include or consist essentially of a metal. The thickness of the cap layer may be less than an absorption length of solar photons in silicon.

The solar cell may include a second junction disposed between the first junction and the cap layer. The second junction may include or consist essentially of at least one III-V material and have a bandgap different from the bandgap of the first junction. The solar cell may include a third junction disposed between the second junction and the cap layer. The third junction may include or consist essentially of at least one III-V material and have a bandgap different from the bandgaps of the first and second junctions.

A contact may be disposed over and/or in direct contact with the cap layer. The contact may include or consist essentially of an alloy of silicon and a metal. The metal may include or consist essentially of at least one of titanium, copper, nickel, cobalt, platinum, or tungsten. The metal may consist essentially or consist of nickel. An anti-reflection coating may be disposed over the cap layer. The anti-reflection coating may include or consist essentially of at least one of silicon nitride and silicon dioxide.

A template layer having a threading dislocation density less than approximately 10⁷ cm⁻² may be disposed over the substrate. A top surface of the template layer may be substantially lattice-matched to a III-V material of the first junction. The template layer may include or consist essentially of a graded-composition layer. The graded-composition layer may include or consist essentially of SiGe and/or GaAsP. A lattice parameter of the template layer may range from approximately 0.555 nm to approximately 0.580 nm.

In another aspect, embodiments of the invention feature a method of power generation including providing a solar cell on a platform and exposing the solar cell to solar radiation, thereby generating an electric current. The solar cell includes or consists essentially of a substrate, a first junction disposed over the substrate, and a cap layer disposed over the first junction. The substrate includes or consists essentially of silicon. The first junction includes or consists essentially of at least one III-V material and has a threading dislocation density of less than approximately 10⁷ cm ². The cap layer includes or consists essentially of silicon. The platform may include or consist essentially of a concentrator system, an aerial vehicle, or a satellite disposed over a substantial portion of the earth's atmosphere. The solar cell may include a second junction disposed between the first junction and the cap layer. The second junction may include or consist essentially of at least one III-V material and have a bandgap different from the bandgap of the first junction. The solar cell may include a third junction disposed between the second junction and the cap layer. The third junction may include or consist essentially of at least one III-V material and have a bandgap different from the bandgaps of the first and second junctions.

In yet another aspect, embodiments of the invention feature an aerial vehicle including an airframe. A solar cell is disposed over (and may be in direct contact with) the airframe. The solar cell includes or consists essentially of a substrate, a first junction disposed over the substrate, and a cap layer disposed over the first junction. The substrate may include or consist essentially of silicon. The first junction may include or consist essentially of at least one III-V material and have a threading dislocation density of less than approximately 10⁷ cm⁻². The cap layer may include or consist essentially of silicon.

In an aspect, embodiments of the invention feature a method for forming a solar cell. The method includes forming, over a substrate, a first junction. The substrate includes or consists essentially of silicon. The first junction includes or consists essentially of at least one III-V material and has a threading dislocation density of less than approximately 10⁷ cm⁻². A cap layer including or consisting essentially of silicon is formed over the first junction. Forming the first junction and forming the cap layer may include or consist essentially of deposition in a single reactor with substantially no exposure of the substrate to oxygen therebetween. Forming the first junction and/or forming the cap layer may include or consist essentially of epitaxial deposition. The first junction may be formed in a first chamber and the cap layer may be formed in a second chamber different from the first chamber. The first junction and the cap layer may be formed in a single chamber.

A portion of the substrate may be removed by at least one of thinning or waffling. A second junction may be provided between the first junction and the cap layer. The second junction may include or consist essentially of at least one III-V material and have a bandgap different from the bandgap of the first junction. A third junction may be provided between the second junction and the cap layer. The third junction may include or consist essentially of at least one III-V material and have a bandgap different from the bandgaps of the first and second junctions.

A metal may be formed over the cap layer and reacted with at least a portion of the cap layer to form a contact layer disposed over the first junction. The contact layer may include or consist essentially of an alloy of silicon and the metal. An unreacted portion of the cap layer may be removed. The metal may include or consist essentially of at least one of titanium, copper, nickel, cobalt, platinum, or tungsten. The metal may consist essentially or consist of nickel. After reacting the metal with at least a portion of the cap layer, an unreacted portion of the cap layer may remain disposed between the first junction and the contact. The unreacted portion of the cap layer may be substantially free of silicon (except for, e.g., any silicon utilized as a dopant therein). The metal may be reacted substantially throughout a thickness of the cap layer, such that the contact is disposed over the first junction with substantially no unreacted portion of the cap layer therebetween.

In another aspect, embodiments of the invention feature a solar cell including a junction having a threading dislocation density of less than approximately 10⁷ cm⁻². The junction includes or consists essentially of at least one III-V material. A contact layer including or consisting essentially of an alloy of silicon and a metal is disposed over a portion of the junction. The junction may be disposed over, and even in direct contact with, a substrate including or consisting essentially of silicon. The contact layer may be disposed in direct contact with the junction. A layer including or consisting essentially of at least one III-V material may be disposed between the contact layer and the junction. The layer may be substantially free of silicon, and/or may include or consist essentially of at least one of GaP or AlP.

These and other objects, along with advantages and features of the present invention herein disclosed, will become more apparent through reference to the following description, the accompanying drawings, and the claims. Furthermore, it is to be understood that the features of the various embodiments described herein are not mutually exclusive and may exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIG. 1 is a schematic cross-sectional diagram of an encapsulated solar cell formed in accordance with various embodiments of the invention;

FIG. 2 is a schematic cross-sectional diagram of the structure of FIG. 1 after the addition of a conductive material for contact formation, in accordance with various embodiments of the invention;

FIGS. 3-5 are schematic cross-sectional diagrams of various embodiments of the structure of FIG. 2 after contact formation;

FIG. 6 is a schematic cross-sectional diagram of the structure of FIG. 3 after front-side and backside metallization in accordance with various embodiments of the invention;

FIG. 7 is a schematic cross-sectional diagram of the structure of FIG. 6 with portions of the substrate removed in accordance with various embodiments of the invention;

FIG. 8 is a partial plan-view schematic diagram of the bottom surface of the structure of FIG. 7 in accordance with various embodiments of the invention;

FIG. 9 is a schematic cross-sectional diagram of a concentrator system incorporating a solar cell formed in accordance with various embodiments of the invention;

FIG. 10 is a perspective illustration of a satellite incorporating a solar cell formed in accordance with various embodiments of the invention;

FIG. 11 is a perspective illustration of an aerial vehicle incorporating a solar cell formed in accordance with various embodiments of the invention; and

FIG. 12 is a schematic cross-sectional diagram of an exemplary encapsulated solar cell in accordance with an embodiment of the invention.

### DETAILED DESCRIPTION

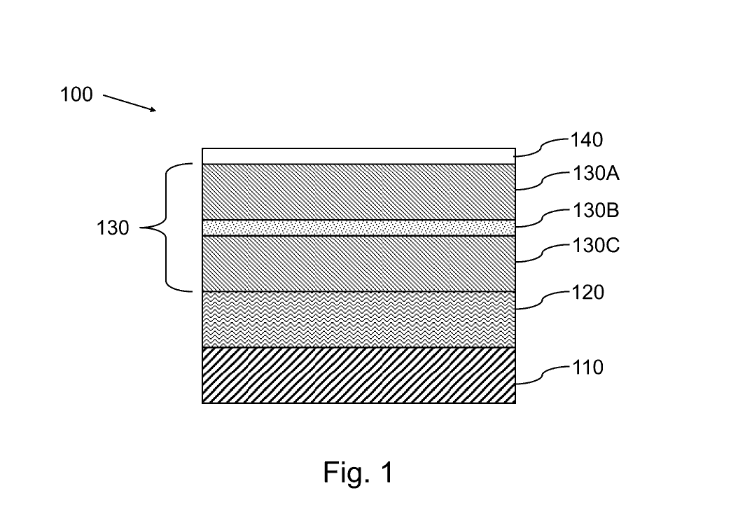

Embodiments of the present invention retain the high-efficiency, single- or multi-junction III-V cell, but embed this cell into silicon (Si), creating a “Si-encapsulated cell,” or SEC. Referring to FIG. 1, in various embodiments, the formation of an SEC 100 begins with the provision of a substrate 110. Substrate 110 preferably includes or consists essentially of Si. Substrate 110 may be, for example, a silicon-on-insulator (SOI) wafer, and/or may have a layer of Si (having, e.g., a different doping level than that of the bulk of the substrate) disposed on a top surface thereof (e.g., in the manner of an “epi-Si wafer”). For example, substrate 110 may include or consist essentially of a layer of Si over another material (which may be polycrystalline), such as silicon carbide. In an embodiment, substrate 110 consists essentially of, or even consists of, Si and various n-type and/or p-type dopants. In another embodiment, substrate 110 includes or consists essentially of a non-Si material that is compatible with Si microelectronics fabrication processes (to which III-V substrates such as GaAs and certain metals such as gold (Au) are typically anathema due to contamination concerns); suitable materials include, e.g., quartz or glass. Such a non-Si-containing substrate 110 may have a top layer of Si disposed thereon. The diameter of substrate 110 may be larger than approximately 100 mm, larger than approximately 200 mm, larger than approximately 300 mm, or even larger than approximately 450 mm. Since in preferred embodiments, substrate 110 includes or consists essentially of Si, substrate 110 generally has a diameter larger than would be possible were a compound semiconductor substrate (e.g., one including or consisting essentially of a III-V or a II-VI material) utilized. In a preferred embodiment, substrate 110 does not include an active solar-cell junction (i.e., does not include a p-n or p-i-n junction designed to convert incident light into electrical current). At least the top surface of substrate 110 may have substantially a (100) crystalline orientation (e.g., substrate 110 may be a (100) Si wafer), although in various embodiments, at least the top surface of substrate 100 is “miscut,” i.e., deliberately misoriented (or “tilted”) away from a major crystallographic plane such as (100). In an embodiment, substrate 110 includes or consists essentially of a (100) Si substrate miscut between approximately 2° and approximately 10° along an in-plane <110> crystallographic direction. In a preferred embodiment, the miscut is approximately 6° along an in-plane <110> crystallographic direction.

In various embodiments, a template layer 120 is disposed over substrate 110. Template layer 120 typically mediates lattice mismatch between substrate 110 and the subsequently added solar-cell junctions (as further described below), thus minimizing the defect density in such junctions. Thus, preferably, a bottom portion of template layer 120 is substantially lattice-matched (e.g., having a lattice-parameter difference less than the approximate difference between the lattice parameters of Ge and GaAs) to the top surface of substrate 110, and a top portion of template layer 120 is substantially lattice-matched to a solar-cell junction formed thereover. In an embodiment, template layer 120 includes or consists essentially of SiGe or GaAsP, at least a portion of which may be graded in composition as a function of the thickness of template layer 120. The thickness of template layer 120 may range between approximately 1 micrometer (μm) and approximately 10 μm, and template layer 120 may include at least one n-type and/or p-type dopant. The graded portion of template layer 120 may have a grading rate (i.e., the rate of change of one component of the layer as a function of position within the layer thickness, e.g., the percentage change of germanium (Ge) as a function of height through the thickness of a SiGe graded layer) ranging between approximately 5%/μm and approximately 50%/μm, and preferably between approximately 10%/μm and approximately 25%/μm. Template layer 120 may include an upper portion having a substantially uniform composition, which may be the approximate composition of an upper portion of a graded portion of template layer 120. The upper, uniform-composition portion may have a thickness ranging between approximately 0.5 μm and approximately 2 μm. In a preferred embodiment, the thickness of the uniform-composition portion is approximately 1 μm. In a preferred embodiment, template layer 120 does not include an active solar-cell junction, and/or includes only one type of dopant (i.e., either n-type or p-type). Herein, omitting an active solar-cell junction is understood to connote the absence of an intentionally formed p-n junction in a particular material or layer. Solar photons may still be absorbed in such a layer, particularly if it has an appreciable thickness. Moreover, unintentional junctions may be formed in the material by, e.g., autodoping during growth of the material and/or other layers. Preferably, the doping level of template layer 120 is of the same type (i.e., either n-type or p-type) and of approximately the same concentration as that of substrate 110 to facilitate electrical connection therethrough.

In a particular embodiment, template layer 120 includes or consists essentially of graded SiGe topped with a layer of Ge, which is approximately lattice-matched to certain III-V semiconductor materials such as GaAs. Template layer 120 is preferably formed as a continuous layer over and in direct contact with substantially all of the top surface of substrate 110. Template layer 120 may be formed by, e.g., an epitaxial deposition process such as chemical-vapor deposition (CVD). In an embodiment, template layer 120 (as well as other layers described herein) is formed in a metallorganic CVD (MOCVD) reactor capable of forming Si, SiGe, Ge, and III-V-based semiconductor materials. The reactor may be a close-coupled shower-head reactor in which gaseous precursors travel only a short distance (e.g., approximately 1 cm) from an unheated injection point to a substrate heated to a desired deposition temperature. In various embodiments, the growth rate of template layer 120 (and/or other layers described herein) is greater than approximately 500 nm/min, or even greater than approximately 700 nm/min. Template layer 120 preferably has a threading dislocation density (e.g., intersecting a top surface thereof) of less than approximately 10⁷/cm², and preferably less than approximately 10⁶/cm² or even less than approximately 10⁵/cm², as measured by plan-view transmission electron microscopy (TEM) or etch-pit density (EPD) measurements.

In certain embodiments, template layer 120 includes or consists essentially of a layer of uniform composition disposed directly over substrate 110. For example, template layer 120 may include or consist essentially of Ge or GaAs formed directly over substrate 110 by, e.g., wafer bonding. However, direct growth of such materials with high lattice mismatch (e.g., greater than approximately 1-2%) to substrate 110 is not preferred due to the elevated defect levels that may result in template layer 120 and/or subsequently formed layers.

Disposed over template layer 120 is at least one junction 130, which may include a p-type-doped subregion 130A, an intrinsically-doped subregion 130B, and an n-type-doped subregion 130C. In various embodiments, subregion 130B may be omitted. The doping types of subregions 130A and 130C may be swapped, and the doping type of subregion 130C preferably matches that of template layer 120 and/or substrate 110. In some embodiments, a p-type-doped subregion 130A and an n-type-doped subregion 130C provides SEC 100 with more resistance to radiation damage (and thus, increased suitability for non-terrestrial applications) than embodiments in which the doping types of these subregions are swapped. Junction 130 includes or consists essentially of at least one compound semiconductor (e.g., III-V) material, such as GaAs, InGaP, AlGaP, AlGaAs, GaP, AlGaSb, GaSb, InP, InAs, InSb, InAlGaP, GaAsP, GaSbP, AlAsP, AlSbP, and/or any alloys or mixtures thereof. Herein, consisting essentially of at least one compound semiconductor material does not preclude the presence of dopants and/or other charge-modifying agents therein. Preferably, junction 130 does not include elemental Si or alloys or mixtures thereof, except for silicon utilized as an n-type or p-type dopant.

Solar cells formed in accordance with various embodiments of the invention may incorporate one or more junctions 130 having bandgaps optimized for collection of solar photons in terrestrial or space applications. For example, a single junction 130 may have a bandgap of approximately 1.38 eV. For cells with two junctions 130, the bandgaps may be approximately 1.12 eV and approximately 1.82 eV. For cells with three junctions 130, the bandgaps may be approximately 0.92 eV, approximately 1.40 eV, and approximately 2.05 eV, or may be approximately 0.92 eV, approximately 1.32 eV, and approximately 1.9 eV. For cells with four junctions 130, the bandgaps may be approximately 0.92 eV, approximately 1.32 eV, approximately 1.80 eV, and approximately 2.38 eV, or may be approximately 0.77 eV, approximately 1.08 eV, approximately 1.46 eV, and approximately 2.0 eV. For cells with five junctions 130, the bandgaps may be approximately 0.92 eV, approximately 1.20 eV, approximately 1.52 eV, approximately 1.94 eV, and approximately 2.48 eV, or may be approximately 0.75 eV, approximately 1.0 eV, approximately 1.28 eV, approximately 1.64 eV, and approximately 2.13 eV. For cells with six junctions 130, the bandgaps may be approximately 0.71 eV, approximately 0.92 eV, approximately 1.15 eV, approximately 1.42 eV, approximately 1.76 eV, and approximately 2.22 eV. These values (and other examples of materials and bandgap energies utilized herein) are merely exemplary; other materials and bandgap energies may be suitable for these and other applications and fall within embodiments of the present invention.

Each of subregions 130A, 130B, and 130C may include or consist essentially of one layer or multiple layers having different doping levels and/or thicknesses, e.g., so-called “base” layers, “emitter” layers, “window” layers, “back surface field” (BSF) layers, etc., as these are known and defined in the art. At least subregion 130C is preferably approximately lattice-matched to an upper portion of template layer 120. Junction 130 preferably has a threading dislocation density (e.g., intersecting a top surface thereof) of less than approximately 10⁷/cm², and preferably less than approximately 10⁶/cm² or even less than approximately 10⁵/cm², as measured by plan-view TEM or EPD measurements. Junction 130 is also preferably at least substantially free of anti-phase boundaries (APBs), e.g., at the interface between junction 130 and template layer 120, as measured by cross-sectional and/or plan-view TEM or EPD measurements. In certain embodiments, the use of a miscut substrate 110 facilitates the formation of a junction 130 that is substantially free of APBs. Junction 130 is preferably formed as a continuous layer (or multiple layers) over and in direct contact with substantially all of the top surface of template layer 120. Junction 130 may be formed by, e.g., an epitaxial deposition process such as CVD. In an embodiment, substrate 110 (e.g., having template layer 120 disposed thereover) is annealed (e.g., at a temperature of approximately 650° C.) prior to formation of junction 130. The anneal may promote high-quality formation of junction 130 by forming a “double-step” surface on substrate 110 or template layer 120.

In embodiments including multiple junctions 130, SEC 100 may include a tunnel junction (not shown) at one or more interfaces between adjoining junctions 130. Such a tunnel junction may include or consist essentially of a highly doped p-n junction (e.g., a p++/n++junction), in which each of the n-type-doped and p-type-doped portions is doped at a level greater than approximately 1×10¹⁹/cm³. The tunnel junction(s) may facilitate current flow through multiple junctions 130 (which might otherwise form low conductivity depleted regions therebetween).

With continued reference to FIG. 1, disposed over one or more junctions 130 is cap layer 140. Cap layer 140 includes or consists essentially of a semiconductor material that is compatible with Si microelectronics fabrication processes, and in a preferred embodiment, cap layer 140 includes or consists essentially of Si. In an embodiment, the thickness of cap layer 140 is less than an absorption length for solar photons in Si (e.g., less than approximately 100 nm), such that the solar response of SEC 100 is not detrimentally affected by absorption in cap layer 140. In a preferred embodiment, the thickness of cap layer 140 is less than approximately 50 nm, or even less than approximately 20 nm. In another embodiment, the thickness of cap layer 140 is greater than the absorption length for solar photons in Si, but at least a portion of cap layer 140 is removed after formation of at least one contact thereto (as further described below). After formation of cap layer 140, junction 130 is substantially, or even completely, encapsulated by a material (e.g., Si) or materials compatible with Si microelectronics fabrication processes. Since cap layer 140 is formed after junction 130, it at least substantially coats all compound-semiconductor material disposed over substrate 110, including at the edge thereof. Thus, in accordance with embodiments of the invention, SEC 100 may be manufactured in a conventional Si fabrication facility since it outwardly resembles a Si wafer (or, at a minimum, a wafer compatible with Si-based microelectronics fabrication).

Cap layer 140 may have a sheet resistance less than approximately 1000 Ω/square. The sheet resistance of cap layer 140 may be even lower, e.g., less than approximately 100 Ω/square. In various embodiments, a cap layer 140 having such a low sheet resistance and including or consisting essentially of Si may deleteriously attenuate incident sunlight, as it may have a thickness greater than an absorption length. Thus, in various embodiments of the invention, cap layer 140 may include or consist of a “sublayer” including or consisting essentially of Si disposed above (and preferably in direct contact with) a sublayer including or consisting essentially of a low-resistance III-V material having a low absorption coefficient for solar photons, e.g., GaP or AlP. Either or both sublayers in cap layer 140 may be doped. As further described below, cap layer 140 or a portion thereof may include various crystallographic defects without substantial impact on the performance of SEC 100.

Cap layer 140 may be incorporated into the design of (and may be disposed beneath) an anti-reflection coating (which typically includes or consists essentially of silicon nitride and/or silicon dioxide, not shown). In an embodiment, the anti-reflection coating and/or another protective layer provides additional encapsulation, particularly at the edge of the substrate. Cap layer 140 may be formed by, e.g., an epitaxial deposition process such as chemical-vapor deposition, and is preferably single-crystalline. In various embodiments, cap layer 140 is polycrystalline or even amorphous. In a preferred embodiment, cap layer 140 is substantially planar, notwithstanding the lattice mismatch between cap layer 140 and junction 130. In various embodiments, a thin (e.g., having a thickness ranging from approximately 1 nm to approximately 10 nm) nucleation layer (not shown) is formed between junction 130 and cap layer 140 in order to improve the nucleation and morphology of cap layer 140. The nucleation layer may include or consist essentially of a compound semiconductor material such as GaAs. In an embodiment, cap layer 140 is formed at a temperature ranging between approximately 550° C. and approximately 750° C. (e.g., approximately 650° C.), or even at lower temperatures, in order to facilitate a high degree of planarity. Cap layer 140 may be formed via use of a gaseous precursor such as silane, disilane, or trisilane to facilitate formation at sufficient growth rates at low formation temperatures. In various embodiments, at least a portion of cap layer 140 is at least partially, or even substantially completely, relaxed to its equilibrium lattice parameter. In such embodiments, cap layer 140 may include a finite concentration of misfit dislocations, threading dislocations, and/or stacking faults, and the threading dislocation density of cap layer 140 may be higher than that of junction 130 by at least approximately an order of magnitude. Cap layer 140 may be polycrystalline and include a finite concentration of grain boundaries, even though junction 130 is preferably single-crystalline. Conventional compound semiconductor-based solar cells avoid the incorporation of severe lattice mismatch (e.g., greater than approximately 1%, greater than approximately 2%, or even greater than approximately 4%) and/or group IV-based materials due to the detrimental effects on the performance (e.g., the efficiency) of such cells due to the introduction of the above-described defects and/or due to deleterious absorption of solar photons. Unexpectedly, the relatively thin thickness of cap layer 140 (and/or the fact that at least portions of cap layer 140 may be removed during processing, as further discussed below) substantially prevents such defects from impacting the performance of SEC 100. In fact, embodiments of the invention including cap layer 140 demonstrate efficiencies substantially identical to, or even greater than, those of solar cells including junction(s) 130 without cap layer 140 (and either on the same or a different substrate 110, and with or without template layer 120). In preferred embodiments, substantially none of the above-described defects present in cap layer 140 propagate into junction 130. Preferably, cap layer 140 is single-crystalline, regardless of the lattice mismatch between it and junction 130 and the amount of lattice relaxation of cap layer 140.

Cap layer 140 may be doped with one or more n-type or p-type dopants, and the doping type and/or doping concentration of cap layer 140 preferably matches that of subregion 130A of junction 130. Typically, the doping type of cap layer 140 will be different from the doping type of substrate 110 and/or template layer 120. In some embodiments, cap layer 140 is “autodoped” either n-type or p-type by incorporation of one or more of the elements present in junction 130. Thus, if the autodoping type is the desired doping type for cap layer 140, a doped cap layer 140 may be formed without the introduction of additional dopant precursors. In contrast, if the autodoping type is that opposite the desired type for cap layer 140, the intentionally introduced dopants are provided at a higher concentration than the autodoping concentration (e.g., greater by at least approximately one order of magnitude). In certain embodiments, the autodoping concentration ranges from approximately 10¹⁹/cm³ to approximately 2×10²⁰/cm³, or even to approximately 5×10²⁰/cm³. In various embodiments, cap layer 140 may be intentionally doped at levels ranging between approximately 10²¹/cm³ to approximately 10²²/cm³.

In various embodiments, template layer 120, junction(s) 130, and cap layer 140 are all formed in the same deposition system with substantially no exposure to oxygen between formation of two or more of the layers. Template layer 120, junction(s) 130, and cap layer 140 may all be formed in a single deposition chamber in the deposition system, or they may be formed in separate dedicated chambers of the same system (each layer may have its own dedicated chamber, or some layers may share a chamber). For example, one chamber of the deposition system may be utilized to form junction(s) 130 or other compound semiconductor-containing layers, and another chamber may be utilized to form Si- and/or SiGe-containing layers, e.g., template layer 120 and cap layer 140.

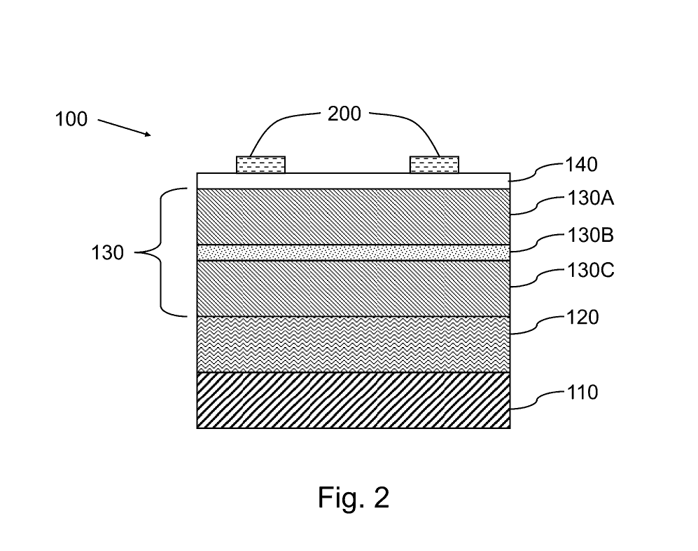

Referring to FIG. 2, contacts to junction 130 are provided via the reaction of at least a portion of cap layer 140 with a conductive material, e.g., a metal. First, metal 200 is formed over cap layer 140 in a specific pattern (e.g., a set of generally parallel lines). In an embodiment, metal 200 is formed over substantially all of the top surface of cap layer 140, patterned by conventional lithography, and etched to form the desired pattern. In another embodiment, the desired pattern is formed by a “lift-off” process, in which photoresist is patterned, metal 200 is formed thereover, and the photoresist is removed, thus carrying away metal 200 in regions where it is not desired. Metal 200 may be formed by, e.g., sputtering or evaporation. The surface of SEC 100 (e.g., cap layer 140) may be cleaned prior to the formation of metal 200 by, e.g., in-situ sputter cleaning.

In preferred embodiments, metal 200 includes or consists essentially of a metal or metal alloy capable of forming an ohmic contact to (and via reaction with) cap layer 140 (e.g., Si) with a specific contact resistance of less than approximately 10⁻⁵ Ω-cm², or even less than approximately 10⁻⁷ Ω-cm². Metal 200 is also preferably compatible with conventional Si microelectronics processing, i.e., does not include carrier “lifetime-killing” metals such as Au or silver (Ag). In an embodiment, metal 200 does not include copper (Cu). In an embodiment, metal 200 includes or consists essentially of at least one of titanium (Ti), cobalt (Co), or nickel (Ni). In other embodiments, metal 200 includes or consists essentially of at least one of platinum (Pt), zirconium (Zr), molybdenum (Mo), tantalum (Ta), or tungsten (W).

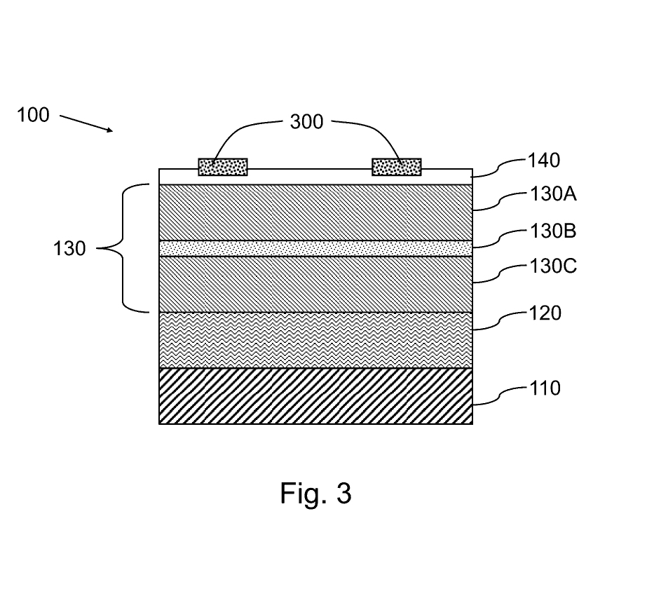

Referring to FIG. 3, contacts 300 are formed by annealing metal 200 at an elevated temperature, e.g., a temperature ranging from approximately 200° C. to approximately 700° C., for a time period ranging from approximately 10 seconds to approximately 120 seconds. During the anneal, metal 200 preferably reacts with at least a portion of cap layer 140, forming contacts 300. Thus, contacts 300 preferably include or consist essentially of a compound including elements found in cap layer 140 and metal 200, e.g., a silicide such as nickel silicide (NiₓSi₁₋ₓ). In an embodiment, each contact 300 has a specific contact resistance of less than approximately 10⁻⁵ Ω-cm², or even less than approximately 10⁻⁷ Ω-cm². Formation of contacts 300 may consume at least a portion of cap layer 140 thereunder; thus, an unreacted portion of cap layer 140 may be disposed beneath each contact 300.

In various embodiments, the contact resistance of contacts 300 may be less than approximately 10⁻⁸ Ω-cm², a level lower than is generally possible using conventional metallurgical contacts to compound semiconductor materials. Thus, SEC 100 may have a higher efficiency than a solar cell incorporating substantially similar (or even identical) junction(s) 130 but lacking capping layer 140 (and thus utilizing standard techniques of contacting to compound semiconductor materials). Since contacts 300 on SEC 100 may have lower contact resistance (and since the lateral resistance between contacts 300 on SEC 100 may be lower, as described above), the surface area of SEC 100 covered by contacts 300 may be less than that required for a solar cell lacking capping layer 140. In an embodiment, contacts 300 (with or without the addition of a front-side conductor, as described below) cover less than approximately 25%, or even less than approximately 10% of the top surface of SEC 100. This decrease in surface coverage required for contacts 300 further increases the efficiency of SEC 100, as more incident solar photons may enter junction 130 (unblocked by contacts 300). This increase in efficiency may be greater than approximately 20%, or even larger.

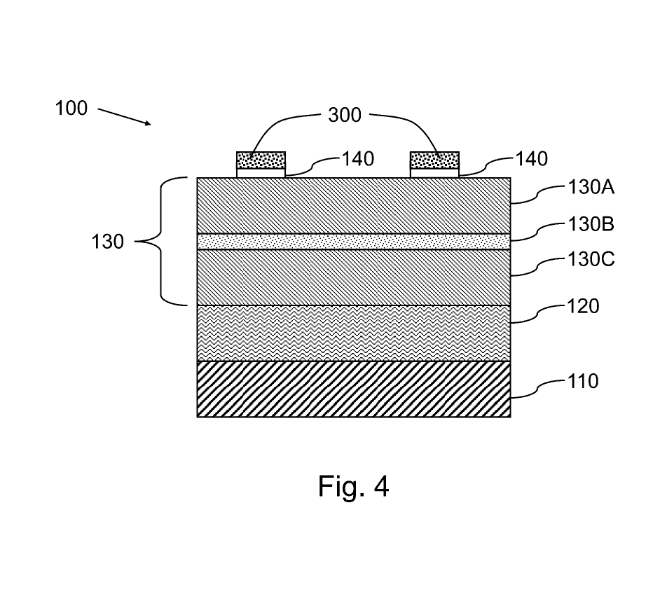

Referring to FIG. 4, in certain embodiments, at least some portions of cap layer 140 not disposed beneath contacts 300 are removed after the formation of contacts 300. (Alternatively, portions of cap layer 140 may be removed before provision of metal 200.) Thus, portions of junction 130 may be exposed between contacts 300. Removal of at least some of the unreacted portions of cap layer 140 may increase performance of SEC 100 by eliminating any deleterious absorption of incident light by cap layer 140. In an embodiment, only a portion (as a function of thickness) of cap layer 140 is removed between contacts 300, leaving a cap layer 140 having a thickness thinner than its original thickness between contacts 300. As mentioned above, the as-formed thickness of cap layer 140 may be thicker than the absorption length for solar photons in Si, and the thickness of cap layer 140 between contacts 300 may range from approximately zero to less than approximately the absorption length for solar photons in Si after removal. Having a thicker cap layer 140 may be advantageous for reducing the contact resistance of contacts 300; however, such thicker cap layers 140 may be detrimental to the performance of SEC 100 due to increased absorption of solar photons therein. Thus, the removal of portions of cap layer 140 between contacts 300 can decouple the typical trade-off between contact resistance and absorption—i.e., embodiments of the present invention enable low contact resistance with substantially no deleterious absorption by cap layer 140.

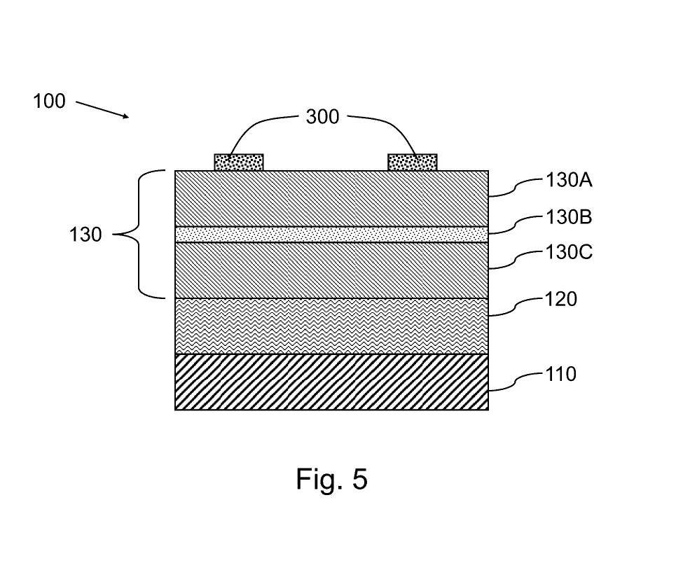

Referring to FIG. 5, in an embodiment, the reaction of cap layer 140 with metal 200 consumes substantially all of the thickness of cap layer 140 disposed beneath metal 200. Thus, contact 300 forms directly above and substantially in contact with junction 130. However, contacts 300 still preferably do not include any compound semiconductor materials found in junction 130, as junction 130 preferably does not react with metal 200 during formation of contacts 300. Although FIG. 5 illustrates an embodiment in which unreacted portions of cap layer 140 (between contacts 300) have been removed, such removal is optional, even in this embodiment. In various embodiments, the reaction of cap layer 140 with metal 200 consumes substantially all of a thickness of a silicon-based sublayer of cap layer 140, and leaves one or more lower sublayers of cap layer 140 disposed therebelow substantially unreacted. In such embodiments, contacts 300 will preferably not include any compound semiconductor materials found in the lower sublayers and/or will be in direct contact with the sublayer disposed directly beneath the silicon-based sublayer. Portions of any or all of the sublayers of cap layer 140 may be removed after the formation of contacts 300.

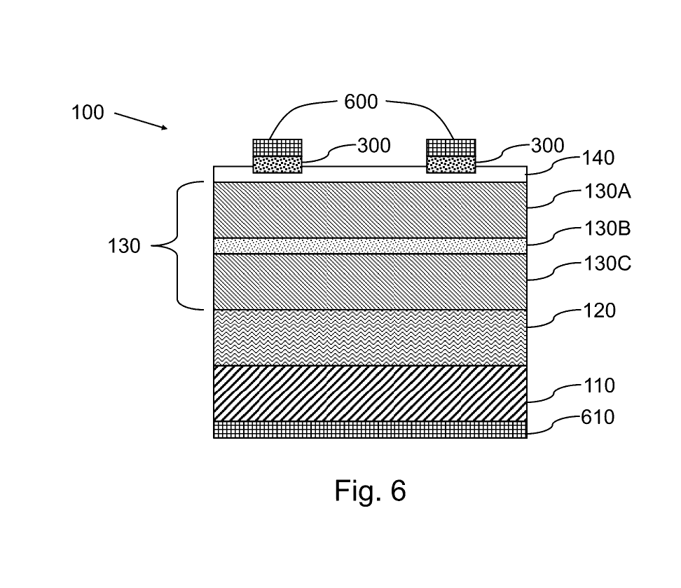

Referring to FIG. 6, metallization of SEC 100 is performed by forming front-side conductors 600 over contacts 300 and back-side conductor 610 on the bottom surface of substrate 110. Both front-side conductors 600 and back-side conductor 610 may include or consist essentially of a conductive material, such as a metal, e.g., Cu or aluminum (Al).

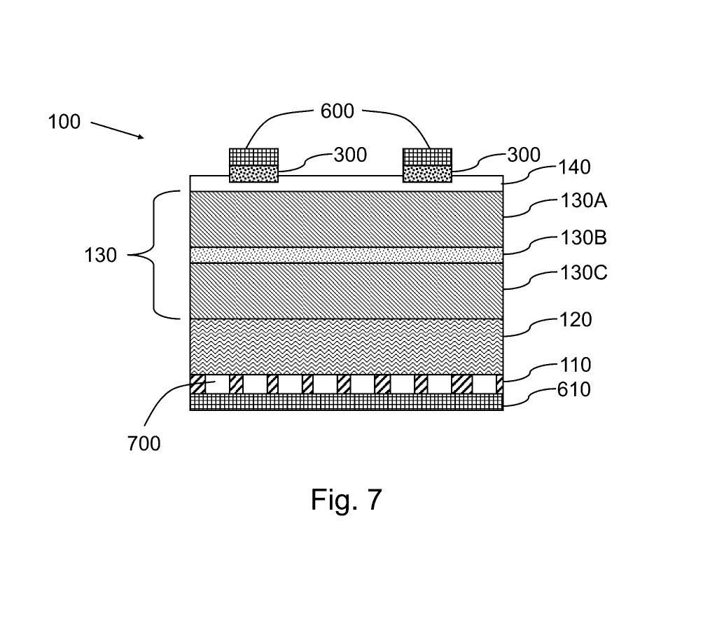

In order to reduce the weight of SEC 100 (and therefore increase the specific power of SEC 100), portions of substrate 110 may be removed before provision of back-side conductor 610. Substrate 110 may be thinned, e.g. by grinding and/or chemical-mechanical polishing (CMP), thus reducing its thickness. In some embodiments, the thickness of substrate 110 is reduced enough to make substrate 110 and SEC 100 substantially flexible. In various embodiments, a flexible SEC 100 may flex to a radius of curvature less than approximately 10 m without substantial decrease in performance. A flexible SEC 100 may be advantageously utilized in applications demanding the provision of solar cells on non-planar surfaces, as the flexible SEC 100 may substantially conform to a desired shape or topography (of, e.g., a wing, as further discussed below). FIG. 7 illustrates an SEC 100 having a thinned substrate 110. In an embodiment, a substantial portion of substrate 110 is thinned, but a portion of substrate 110 at or near its edge has a thickness larger than that of the thinned portion (and may be substantially equal to the thickness of unthinned substrate 110). Such a configuration may lend SEC 100 increased stability during handling.

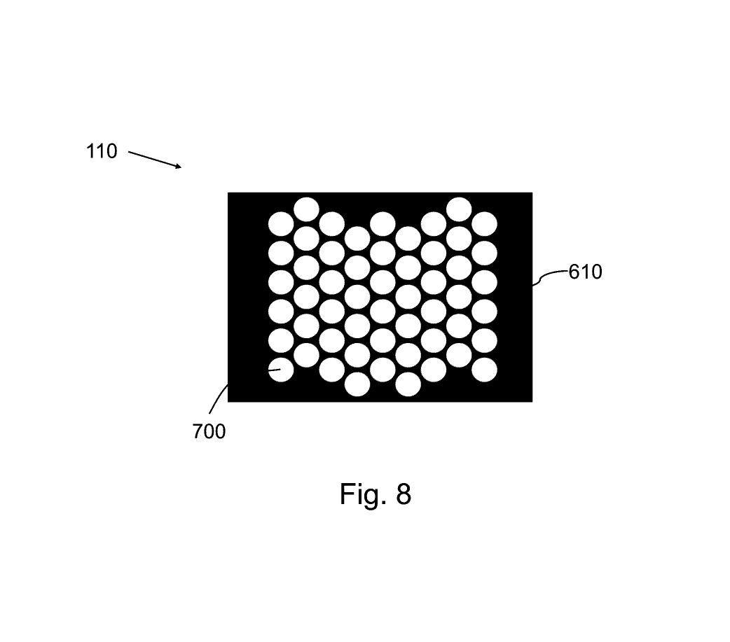

With further reference to FIG. 7, in addition to (or instead of) thinning substrate 110, portions of substrate 110 may be removed in a “waffling” process. In this process, portions of substrate 110 are removed, thus forming recesses 700. Recesses 700 may remain empty, or may be filled with a material (e.g., epoxy) having a lower density than that of substrate 110. Although FIG. 7 depicts recesses 700 as extending through substantially the entire thickness of substrate 110, in some embodiments, recesses 700 may extend only through a portion of the thickness of substrate 110. In certain embodiments, such as those used with concentrators, it is advantageous for recesses 700 to have high thermal and/or electrical conductivity, and thus, recesses 700 may be filled with a metal such as Al, Cu, and/or alloys or mixtures thereof. In various embodiments, thinning and/or waffling substrate 110 may remove more than approximately 25%, or even more than approximately 50% of the volume (and/or weight) of substrate 110. FIG. 8 illustrates a plan view of the bottom of SEC 100 after waffling of substrate 110. The embodiment of FIG. 8 shows recesses 700 formed in a six-fold symmetric “honeycomb” pattern; however, other patterns may also be advantageously utilized. Moreover, FIG. 8 depicts recesses 700 has having substantially circular cross-sections; however, other cross-sectional shapes (e.g., polygons such as hexagons) may also be advantageously utilized. Further, it should be noted that FIG. 8 depicts either a substrate 110 having a quadrilateral shape or only a quadrilaterally shaped portion of substrate 110; substrate 110 may have shape (and cross-sectional area) that is substantially non-quadrilateral, e.g., circular.

In certain embodiments, SEC 100 is formed, including contacts 300, front-side conductors 600, and back-side conductors 610 without external exposure of any compound semiconductor material from junction(s) 130. Such formation facilitates the high-volume production of SEC 100 in a Si-compatible manufacturing facility with substantially no contamination of equipment therein.

The electrical performance of SEC 100 in accordance with various embodiments of the invention is at least equal to that of conventional compound semiconductor-based solar cells. As measured by certain characteristics, the performance of SEC 100 may exceed that of conventional compound semiconductor-based solar cells (lacking, e.g., cap layer 140, particularly a cap layer 140 including or consisting essentially of Si, and/or a substrate 110 including or consisting essentially of Si) by a factor of approximately 2, a factor of approximately 4, or even a factor of approximately 10. SEC 100 including a single junction 130 may have an air-mass-zero (“AM0,” corresponding to the solar spectrum outside the atmosphere of the earth) efficiency ranging from between approximately 18% and approximately 28%. SEC 100 including a single junction 130 may have an air-mass-1.5 (“AM1.5,” corresponding to the solar spectrum on the surface of the earth with a solar zenith angle of approximately 48°) efficiency ranging between approximately 20% and approximately 30%. SEC 100 including two junctions 130 may have an AM0 efficiency ranging from between approximately 25% and approximately 35%. SEC 100 including two junctions 130 may have an AM1.5 efficiency ranging from between approximately 25% and approximately 40%. SEC 100 including three junctions 130 may have an AM0 efficiency ranging from between approximately 30% and approximately 40%. SEC 100 including three junctions 130 may have an AM1.5 efficiency ranging from between approximately 30% and approximately 45%. SEC 100 may also have a fill factor ranging from approximately 0.8 and approximately 0.9 and/or an open-circuit voltage ranging between approximately 1.5 V and approximately 4.0 V (preferably ranging between approximately 3.3 V and approximately 4.0 V).

The specific power of SEC 100, e.g., SEC 100 including three junctions 130, may range between approximately 800 watts/kilogram (W/kg) and approximately 1000 W/kg, even without thinning or waffling of substrate 110. After thinning and/or waffling of substrate 110, the specific power of SEC 100 may range between approximately 1500 W/kg and approximately 2000 W/kg, or even higher. Such high specific power levels may facilitate high power outputs for weight-sensitive applications such as satellites or aerial vehicles (as further described below). The specific mass of SEC 100 may range between approximately 0.08 kg/m² and approximately 0.2 kg/m², values significantly lower than those of conventional compound semiconductor-based solar cells.

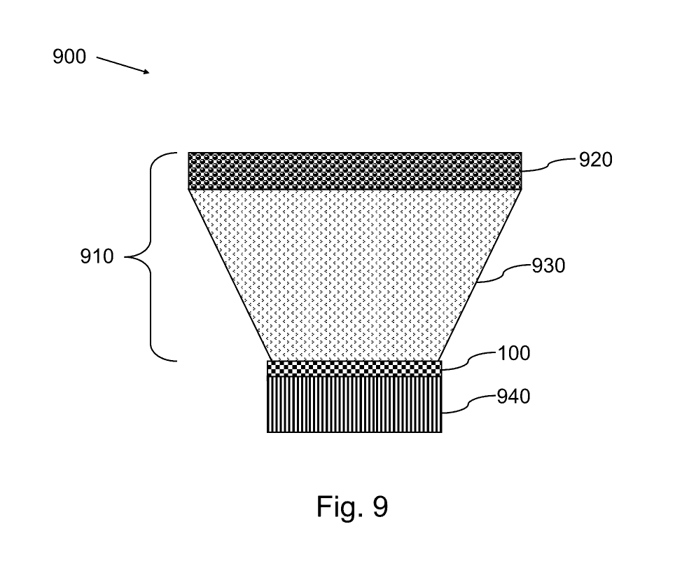

In accordance with various embodiments of the invention, SEC 100 is advantageously utilized in a variety of applications. Referring to FIG. 9, a concentrator system 900 includes SEC 100 and, disposed thereabove, a concentrator 910. Concentrator 910 focuses incoming solar energy onto SEC 100, increasing the number of absorbed solar photons and increasing the amount of power (and current) generated by SEC 100. Concentrator 910 may include several components, e.g., a lens 920 and a focusing system 930. Lens 920 serves to focus solar energy impinging thereon toward an SEC 100 having a smaller cross-sectional area. Lens 920 may be or include, e.g., a Fresnel lens or a prismatic layer, and may include or consist essentially of a substantially transparent material such as glass or plastic. Focusing system 930 increases the amount of concentration performed by concentration system 900 by directing (by, e.g., via internal reflection) light from lens 920 toward SEC 100. Because concentrated solar energy (and the current generated therefrom) may substantially increase the temperature of SEC 100, SEC 100 may be disposed above and in direct contact with a heat sink 940. Heat sink 940 preferably includes or consists essentially of a material with high thermal conductivity, e.g., a metal or metal alloy. Concentrator system 900 may also include other components (not pictured), such as a housing (to support and contain concentration system 900). Concentrator 910 may also include other components to improve light capture and focusing, such as one or more layers of organic materials (e.g., dyes) that absorb and retransmit light.

Conventional solar cells under concentration, particularly those under high concentration (e.g., greater than approximately 100 suns), typically require at least approximately 50% of their surfaces covered by metal contacts in order to adequately handle the large amounts of electrical current produced thereby. A contributing factor for the need for a large contact area is the high resistivity surface layer(s) frequently incorporated into conventional solar cell designs (e.g., layers incorporating materials such as InGaP). The large amount of surface coverage inhibits the performance (e.g., the efficiency) of the solar cell, as the covered area is basically unavailable for absorption of solar photons and conversion thereof into electrical power. In contrast, due to the higher conductivity of cap layer 140 on SEC 100, particularly when cap layer 140 includes or consists essentially of Si, SEC 100 experiences substantially less resistive loss at its surface. SEC 100 may include a cap layer 140 and/or contacts 300 that have a higher conductivity than surface layers of conventional compound semiconductor-based solar cells (e.g., layers including materials such as InGaP). Therefore, SEC 100 in concentration system 900 may include a surface coverage of conductors (e.g., contacts 300 or front-side conductors 600) and/or other substantially optically opaque materials of less than approximately 25%, or even less than approximately 10%. In turn, this low amount of surface coverage enhances the amount of solar energy absorbed and converted into electrical energy by SEC 100.

Concentration system 900 may incorporate single- or dual-axis tracking (e.g., to maximize the amount of solar photons impinging thereon as the location of the sun changes) in order to improve performance. Concentration system 900 may enable superior concentration ratios, e.g., concentration ratios ranging between approximately 2 suns and approximately 1000 suns.

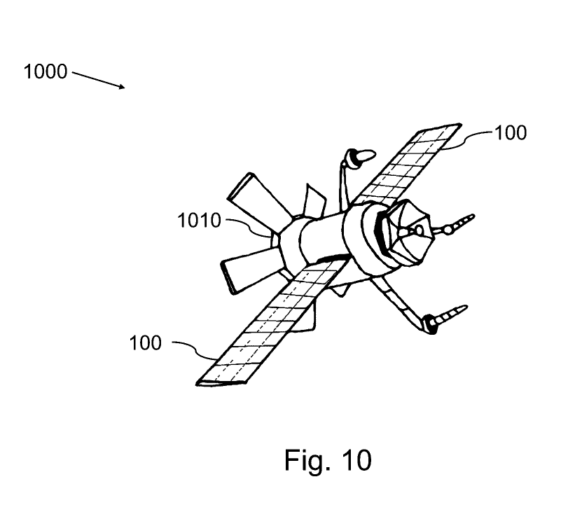

Referring to FIG. 10, SEC 100 may be advantageously utilized as a power source for a satellite 1000. The high specific power of SEC 100 enables a larger amount of power generation at a lower weight; thus, the cost and amount of propellant required to send satellite 1000 is less than if satellite 1000 incorporates conventional solar cells. Satellite 1000 may include a plurality of SECs 100, preferably pointed as directly as possible toward the sun, as well as a payload 1010. Payload 1010 may include a variety of components, including communications equipment, sensors, and the like.

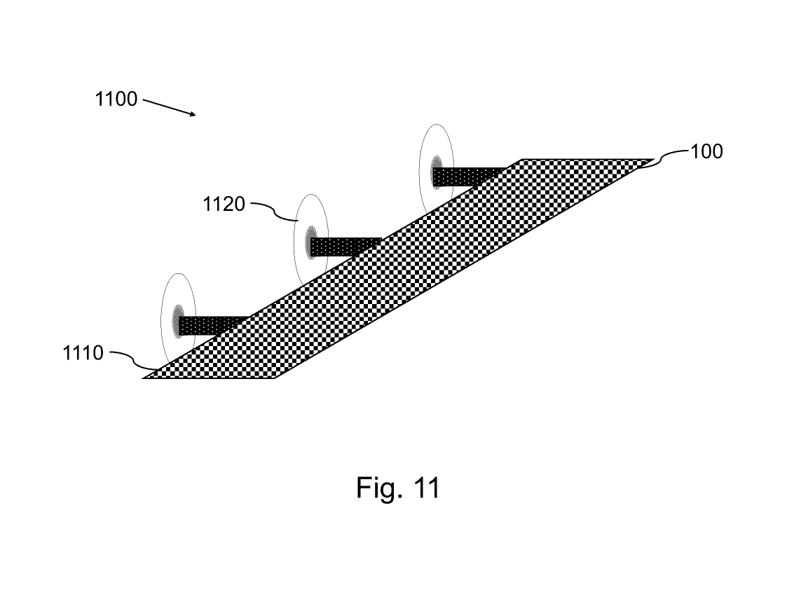

Referring to FIG. 11, SEC 100 may also be advantageously utilized as a power source for an aerial vehicle 1100. Aerial vehicle 1100, which may be manned or unmanned, includes an airframe 1110 and one or more propellers 1120 (illustrated in motion), and may be a “heavier-than-air” aircraft (as opposed to, e.g., a blimp- or dirigible-based craft) capable of flight at altitudes ranging from approximately 40,000 feet to approximately 100,000 feet above the earth's surface. Airframe 1110 may include or consist essentially of a low-density material, e.g., a composite material incorporating carbon fiber as is known in the art. Although airframe 1110 is illustrated as a roughly rectangular “wing,” airframe 1110 may take a variety of shapes, and may be substantially flat, curved, or even segmented. The wingspan of aerial vehicle 1100 may range from approximately 50 meters (m) to approximately 300 m, and the surface area of aerial vehicle 1100 and or airframe 1100 may range from approximately 100 m² to approximately 500 m². Aerial vehicle 1100 may also include (not pictured) components such as avionics and an energy storage system such as a battery or fuel cell (for, e.g., storage of energy to be used at night or in darkness). Aerial vehicle 1100 may also include structures such as fins and/or rudders for controlling its direction of travel. A plurality of SECs 100 is disposed atop airframe 1100 and covers at least approximately 50% of the surface area thereof (and even up to approximately 85% or even approximately 100%). SECs 100 provide the motive power for aerial vehicle 1100, and such power may be sufficient to power aerial vehicle 1100 for sustained flights of up to approximately 1 to approximately 5 years, 24 hours per day (e.g., power ranging from approximately 3 to approximately 8 kW, preferably approximately 5 kW). Aerial vehicle 1100 may also include a payload, e.g., sensors, cameras, and/or communications equipment, that may weigh up to approximately 1000 pounds (or even more).

### EXAMPLE

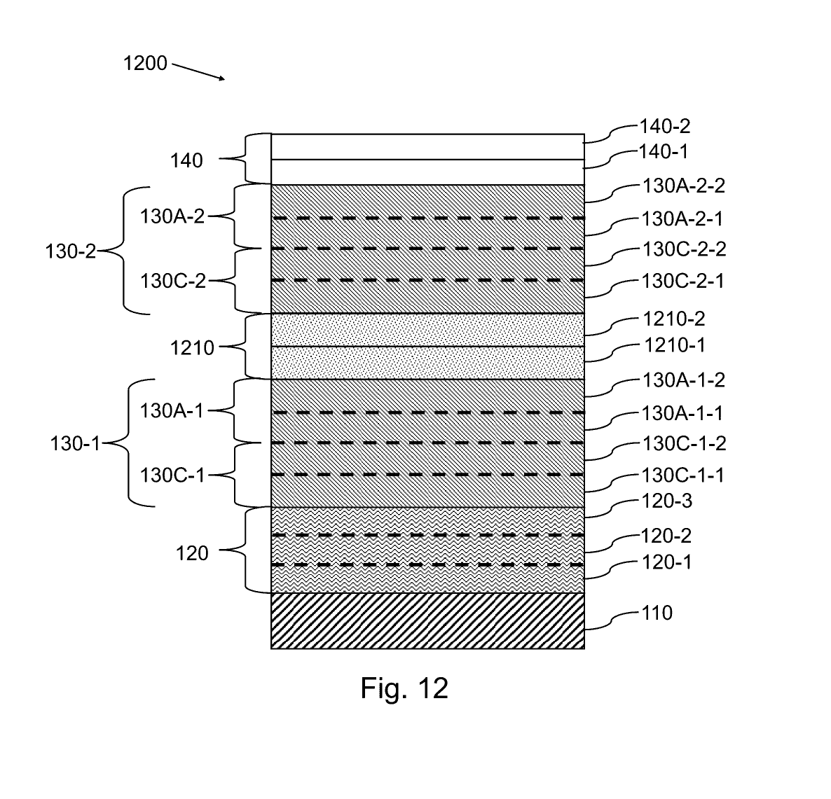

FIG. 12 depicts an exemplary SEC 1200 incorporating two junctions 130 prior to addition of contacts 300. SEC 1200 includes a substrate 110 consisting essentially of (or even consisting of) n+-doped Si. Template layer 120 includes or consists essentially of an n+-doped SiGe graded layer 120-1 (graded, e.g., from approximately 0% Ge to approximately 100% Ge), an n+-doped Ge uniform composition layer 120-2, and an n+-doped GaAs buffer layer 120-3. GaAs buffer layer 120-3 has a thickness of approximately 250 nm and a doping level of approximately 2×10¹⁸/cm³.

SEC 1200 includes first junction 130-1 and second junction 130-2. First junction 130-1 includes or consists essentially of subregions 130A-1 and 130C-1. Subregion 130C-1, in turn, includes or consists essentially of an n+-doped In_{0.49}Ga_{0.51}P BSF layer 130C-1-1 (having a thickness of approximately 100 nm and a doping level of approximately 2×10¹⁸/cm³) and an n-doped GaAs base layer 130C-1-2 (having a thickness of approximately 1400 nm and a doping level of approximately 2×10¹⁷/cm³). Subregion 130A-1 includes or consists essentially of a p+-doped GaAs emitter layer 130A-1-1 (having a thickness of approximately 250 nm and a doping level of approximately 2×10¹⁸/cm³) and a p+-doped In_{0.49}Ga_{0.51}P window layer 130A-1-2 (having a thickness of approximately 40 nm and a doping level of approximately 3×10¹⁸/cm³).

Second junction 130-2 includes or consists essentially of subregions 130A-2 and 130C-2. Subregion 130C-2, in turn, includes or consists essentially of an n+-doped In_{0.47} (Al_{0.7}Ga_{0.3})_{0.53} P BSF layer 130C-2-1 (having a thickness of approximately 30 nm and a doping level of approximately 2×10¹⁸/cm³) and an n-doped In_{0.49}Ga_{0.51}P base layer 130C-2-2 (having a thickness of approximately 450 nm and a doping level of approximately 7×10¹⁶/cm³). Subregion 130A-2 includes or consists essentially of a p+-doped In_{0.49}Ga_{0.51}P emitter layer 130A-2-1 (having a thickness of approximately 50 nm and a doping level of approximately 2×10¹⁸/cm³) and a p+-doped In_{0.47} (Al_{0.7}Ga_{0.3})_{0.53}P window layer 130A-2-2 (having a thickness of approximately 30 nm and a doping level of approximately 4×10¹⁸/cm³).

Disposed between and in direct contact with first junction 130-1 and second junction 130-2 is tunnel junction 1210. Tunnel junction 1210 includes a p++-doped GaAs layer 1210-1 (having a thickness of approximately 30 nm and a doping level of approximately 2×10¹⁹/cm³) and an n++-doped GaAs layer 1210-2 (having a thickness of approximately 30 nm and a doping level of approximately 2×10¹⁹/cm³).

Cap layer 140 is disposed over second junction 130-2, and includes or consists essentially of a p++-doped GaAs layer 140-1 (having a thickness of approximately 50 nm and a doping level of approximately 1×10¹⁹/cm³) and a p++-doped Si layer 140-2 (having a thickness of approximately 30 nm and a doping level of approximately 1×10¹⁹/cm³).

SEC 1200 has an AM0 efficiency ranging from between approximately 25% and approximately 31%. SEC 1200 has an AM1.5 efficiency ranging from between approximately 28% and approximately 35%.

The terms and expressions employed herein are used as terms and expressions of description and not of limitation, and there is no intention, in the use of such terms and expressions, of excluding any equivalents of the features shown and described or portions thereof. In addition, having described certain embodiments of the invention, it will be apparent to those of ordinary skill in the art that other embodiments incorporating the concepts disclosed herein may be used without departing from the spirit and scope of the invention. Accordingly, the described embodiments are to be considered in all respects as only illustrative and not restrictive.

What is claimed is:

1. A method for forming a solar cell, the method comprising:
forming, over substantially all of a top surface of a substrate comprising silicon, a first junction comprising at least one III-V material and having a threading dislocation density of less than approximately 10⁷ cm⁻²;
forming, over substantially all of a top surface of the first junction, a cap layer comprising a first layer consisting essentially of doped or undoped silicon;
forming a metal over a first region of a top surface of the cap layer;
reacting the metal with the cap layer to form a contact layer disposed over the first junction, the contact layer comprising an alloy of silicon and the metal;
removing at least a portion of the cap layer in a second region proximate the first region, thereby exposing a III-V material; and
after the exposure of the III-V material in the second region, performing at least one additional processing step, thereby forming a solar cell comprising the first junction.

2. The method of claim 1, wherein, prior to the removal of the at least a portion of the cap layer in the second region, a thickness of the cap layer in the second region is less than an absorption length of solar photons in silicon.

3. The method of claim 1, wherein the removal of the at least a portion of the cap layer in the second region exposes, without any layer thereover in the second region, a portion of at least one of (i) the first junction, (ii) a second junction disposed over the first junction, or (iii) a third junction disposed over a second junction disposed over the first junction.

4. The method of claim 1, further comprising providing a second junction between the first junction and the cap layer, the second junction comprising at least one III-V material and having a bandgap different from a bandgap of the first junction.

5. The method of claim 4, further comprising providing a third junction between the second junction and the cap layer, the third junction comprising at least one III-V material and having a bandgap different from the bandgaps of the first and second junctions.

6. The method of claim 1, wherein the contact layer consists essentially of an alloy of silicon and the metal.

7. The method of claim 1, wherein the metal comprises at least one of titanium, copper, nickel, cobalt, platinum, or tungsten.

8. The method of claim 1, wherein the metal consists essentially of nickel.

9. The method of claim 1, wherein, after reacting the metal with at least a portion of the cap layer, an unreacted portion of the cap layer remains disposed between the first junction and the contact layer.

10. The method of claim 9, wherein the unreacted portion of the cap layer is substantially free of silicon.

11. The method of claim 1, wherein the metal is reacted substantially throughout a thickness of the cap layer, such that the contact layer is disposed over the first junction with substantially no unreacted portion of the cap layer therebetween.

12. The method of claim 1, further comprising:
forming a template layer over substantially all of the top surface of the substrate, the template layer having a threading dislocation density less than approximately 10⁷ cm⁻²,
wherein (i) a top surface of the template layer is substantially lattice-matched to a III-V material of the first junction, and (ii) the template layer comprises a graded-composition layer comprising at least one of SiGe or GaAsP.

13. The method of claim 1, wherein a threading dislocation density of the cap layer is higher than the threading dislocation density of the first junction by at least an order of magnitude.

14. The method of claim 1, wherein the first layer of the cap layer is substantially amorphous or substantially polycrystalline.

15. The method of claim 1, wherein the cap layer comprises, disposed under the first layer, a second layer comprising a doped or undoped III-V material different from the at least one III-V material of the first junction.

16. The method of claim 15, wherein the second layer consists essentially of at least one of (i) doped or undoped GaP or (ii) doped or undoped AlP.

17. The method of claim 1, further comprising removing a portion of the substrate by at least one of thinning or waffling.

18. The method of claim 1, wherein forming the first junction and forming the cap layer comprise deposition in a single reactor with substantially no exposure of the substrate to oxygen therebetween.

19. The method of claim 18, wherein the first junction is formed in a first chamber and the cap layer is formed in a second chamber different from the first chamber.

20. The method of claim 18, wherein the first junction and the cap layer are formed in a single chamber.
